(19) United States
(12) Patent Application Publication
(10) Pub. No.: US 2002/0034837 A1
(43) Pub. Date: Mar. 21, 2002

(54) Method of activating CdTe thin-film solar cells

(76) Inventors: Manuel D. Campo, Hanau (DE); Dieter Bonnet, Friedrichsdorf (DE); Rainer Gegenwart, Erfurt (DE); Jutta Beier, Hofheim (DE)

Correspondence Address: QUARLES & BRADY LLP, 411 E. WISCONSIN AVENUE, SUITE 2040, MILWAUKEE, WI, 53202-4497, US

(21) Appl. No.: 09/908,384

(22) Filed: Jul. 18, 2001

(30) Foreign Application Priority Data
Jul. 26, 2000 (EP) 00 115 995.3

(51) Int. Cl. H01L 21/00

(52) U.S. Cl. 438/57; 438/58; 438/95

(57) ABSTRACT

In a method of activating CdTe thin-film solar cells, substrates provided with a CdS layer and the CdTe layer are exposed to a gas mixture containing HCl, oxygen and nitrogen at an elevated temperature and at a total pressure below atmospheric pressure, the HCl partial pressure of the gas mixture being set at levels between 0.002 % and 0.2 % of the total gas pressure.

### FIELD OF INVENTION

This invention relates to a method of activating CdTe thin-film solar cells in which substrates which are provided with the CdTe layer are exposed to a gas mixture containing HCl at an elevated temperature.

### BACKGROUND OF THE INVENTION

Activation of CdTe thin-film solar cells has been performed successfully for several years using CdCl₂. These may be CdTe/CdS thin-film solar cells such as those disclosed in European Patent 535,522 A2 corresponding to U.S. Pat. No. 5,304,499 and used as the basis of the investigations forming the background of the present invention. According to European Patent 535,522 A2 and U.S. Pat. No. 5,304,499 which is incorporated herein by reference, layer deposition is performed by a CSS method, and the activation which is performed after applying the CdTe layer takes place at an elevated temperature of approximately 400° C. preferably in gaseous CdCl₂ and at a reduced pressure. However, working with gaseous CdCl₂ involves strict safety requirements because of the water solubility of the cadmium compound.

Therefore, there have already been attempts to use gaseous HCl or chlorine gas instead of performing the activation with gaseous CdCl₂. However, the results have not been satisfactory, and problems have occurred in the form of unwanted precipitates. The report “Processing and Modeling Issues for Thin-Film Solar Cell Devices,” Annual Report to National Renewable Energy Laboratory under Subcontract No. XAV-3-13170-01, January 1995, Birkmire et al. of the Institute of Energy Conservation, University of Delaware, explains that when an HCl gas with an argon carrier gas or an argon/oxygen carrier gas with 4% HCl/96% Ar or 4% HCl/48% Ar/48% O₃₂ is used, better electric properties are achieved if oxygen is used at the same time. However, in the treatment with 4% HCl/48% Ar/48% O₂, it was necessary to wash off surface deposits which contained chlorine and were formed during activation at a substrate temperature of 400° C. In a later publication by the same institute regarding experiments conducted with HCl (Proc: 25^{th} PVSC, May 13-17, 1996, Washington, D.C., Meyers et al. of the Institute of Energy Conversion, University of Delaware, “HCl Vapor Post-Deposition Heat Treatment of CdTe/CdS Films”), reference is again made to precipitates in the form of CdCl₂ which are formed when oxygen is added. These have been dominant in comparison with other effects such as oxygen doping. Therefore, no oxygen was added here, and only argon was used as the carrier gas. According to this publication, the efficiency of the cells was found to have a great dependence on the HCl concentration, relative to the argon concentration, with better values being found for higher HCl concentrations above 5%.

In addition, work has been done with an HCl/nitrogen gas (Proc: 1^{st} WCPEC, Dec. 5-9, 1994, Hawaii, T. X. Zhou et al., Solar Cells, Inc., “Vapor Chloride Treatment of Polycrystalline CdTe/CdS Films”). The HCl/nitrogen gas mixture was produced by bubbling nitrogen gas through a vessel containing a concentrated hydrochloric acid solution. For 0.25 cm² solar cells that were subjected to a treatment with the gas mixture produced in this way, an efficiency of 8.4% was found at a substrate temperature of 400° C. This efficiency was also determined for 10-minute treatments with a comparable premixed HCl/nitrogen gas mixture and large-area coatings. In the case of a diluted gas mixture of chlorine and nitrogen, a higher efficiency between 9% and 10% was observed locally in individual layer areas, but this type of activation is regarded more critically.

### BRIEF SUMMARY OF THE INVENTION

The present invention provides a method of activating CdTe thin-film solar cells in which substrates have been provided with a CdS and a CdTe layer. In one embodiment the method includes exposing the solar cells to a gas mixture containing HCl, oxygen and nitrogen at a total gas pressure below atmospheric pressure, and the HCl partial pressure of the gas mixture is set at levels between 0.002% and 0.2% of the total gas pressure. In another embodiment, the method includes exposing the solar cells to a gas mixture containing HCl, oxygen and nitrogen at a total gas pressure below atmospheric pressure, and the oxygen partial pressure of the gas mixture is adjusted to levels between 5% and 25% of the total gas pressure.

It is an object of the present invention to provide the most inexpensive and efficient possible method of activating CdTe thin-film solar cells with which a high efficiency can be achieved. This object is achieved by the subject matter of the independent claims. Advantageous further developments are defined in the subclaims.

### DETAILED DESCRIPTION OF THE PREFERRED EMBODIMENTS

A gas mixture containing HCl, oxygen and nitrogen is used for activation at a total gas pressure which is below atmospheric pressure. In numerous experimental series with gas mixtures of different compositions, it has been found that a very high efficiency of approximately 12% and in some cases more than 12% can be achieved with such a gas mixture at a very low HCl partial pressure between 0.002% and 0.2% of the total gas pressure for a wide range of different oxygen and nitrogen concentrations. The preferred range with the highest efficiencies observed is achieved at an HCl partial pressure between 0.05% and 0.15%, i.e., approximately 0.1%.

Alternatively, the HCl concentration can be increased in a wide range from the very low values indicated above to a partial pressure of more than 20% in the case of a oxygen partial pressure adjusted to values between approximately 5% and 25% of the total gas pressure without a drop in efficiency to levels below 12%. Up to an HCl partial pressure of approximately 2%, an efficiency of more than 12% can thus readily be achieved with the oxygen partial pressure thus limited. However, if the process is carried out with a significantly higher oxygen content, then these efficiency values are obtained only for the especially low HCl partial pressure values mentioned above according to claim 1.

The fact that these effects found by the inventors of the present application have not yet been described analytically in no way restricts the advantages of the process being possible now. In fact, achieving such a high efficiency with the low and extremely low HCl content in the nitrogen and oxygen atmosphere indicated here is actually sensational from several regards for implementation of a method suitable for mass activation for solar cell modules. Thus, on the one hand, the activation gas can be freed of HCl very easily by simply washing out the HCl, while on the other hand, the possible HCl concentrations are so low that safety measures can be reduced to a minimum. Furthermore, virtually no etching of the CdTe surface could be detected.

The efficiency is relatively independent of fluctuations in the HCl concentration, which can also vary at a high oxygen content between 0.002% and 0.2% HCl partial pressure, i.e., over two powers of ten. Therefore, no complicated control measures are necessary for the HCL partial pressure.

If the oxygen partial pressure is then also set at a value of 20%, the efficiency is practically independent of any fluctuations in HCl concentration. However, this means that only normal air under a reduced pressure can be used for successful activation of the cells with completely harmless amounts of added HCl gas, which are extremely low, need not be adjusted precisely and are not critical with regard to fluctuations in concentration, and an efficiency of more than 12% can be achieved in this way. Thus, efficient, inexpensive, environmentally friendly and nontoxic activation methods are possible.

When working under the conditions disclosed herein, no precipitates and no residue on the CdTe layers were observed in any of the numerous experiments. Whether this is a direct result of the reduced pressure that was established has not yet been clarified, especially since, as explained below, the pressure could be varied over a wide range.

The total pressure is preferably set at a level of more than 100 mbar. In the experimental series, a total pressure of approximately 500 mbar proved appropriate, especially since no positive effects on efficiency could be observed even at much lower pressure levels by further increasing the pressure starting form said lower pressure levels. Hence, it is not worthwhile to use a higher total pressure. A reasonable upper limit for the total pressure from the standpoint of gas consumption can be regarded as 600 mbar.

Activation is preferably accomplished with continuous flow of the gas mixture through an activation chamber in which the substrates are heated to the desired activation temperature in a manner known per se. Then the gas mixture is kept in continuous flow through the chamber, after having initially built up the desired gas pressure, so that the initial pressure is not increased in the course of the activation period.

However, it was also possible to first establish a total gas pressure of 500 mbar, for example, in a chamber without continuous gas flow through the chamber. The gas pressure automatically increased gradually to 800 mbar in the following 15 or 20 minutes after having established the initial pressure due to the expansion of the gas caused by the hot substrate. No negative effect on efficiency could be observed in this way. This also illustrates the high stability and reliability of the method according to this invention.

The substrate temperature should be set at levels of more than 370° C. from the standpoint of achieving the highest possible efficiency. A very good efficiency was achieved at temperatures between 390° C. and 420° C. in the experimental series. This shows that even the setting of the substrate temperature is not critical. Values of 500° C. or more are not preferred, especially since the cells that are preferably used in the method according to this invention have an inexpensive float glass substrate.

The activation is preferably performed in 1 to 15 minutes. In principle, it is possible to reduce the activation time by increasing the substrate temperature. If an especially high efficiency is not needed, the activation time at a temperature of more than 450° C. can be reduced as necessary to a minimum time in the range of 15 seconds.

If the process is not to be carried out with a mixture resembling air with regard to the oxygen/nitrogen composition, then the nitrogen partial pressure is preferably set at a level of more than 20%, the oxygen partial pressure is set at a level of less than 60%, and the HCl partial pressure is set a level of less than 0.15%, at which especially high efficiencies can be achieved even at an elevated oxygen partial pressure.

One possible embodiment in which an efficiency of more than 12% is achieved includes the following process parameters:

| | |
|---|---|
| Substrate temperature: | 390° C. |
| Total gas pressure: | 500 mbar |
| Oxygen partial pressure: | approximately 20% |
| Nitrogen partial pressure: | approximately 80% |
| HCl partial pressure | approximately 0.1% |

To do so, air was purified through filters (6TF-MM of NUPRO), and the proper reduced pressure was established by means of a needle valve (SS-SS6-MM of NUPRO). The HCl gas was also introduced into the quartz chamber from a gas bottle, likewise through a needle valve. Furthermore, the chamber had pumping devices (2033 CP⁺ and CFF Turbo of Alcatel)and several pressure meters (Thermovac TM20S and Penningvac PM310 of Leybold Heraeus). The substrate was secured on a graphite substrate holder and was heated in vacuo using halogen lamps before beginning the introduction of gas. The substrate was a float glass substrate according to European Patent 535,522 A2 corresponding to U.S. Pat. No. 5,304,499, coated with a TCO layer, a CdS layer and a CdTe layer. The substrate was activated with the above gas mixture for a period between 10 minutes and 15 minutes. For measuring the current/voltage characteristic and for determining fill factors and efficiency, the activated specimens were etched according to a standard etching process with a mixture of nitric and phosphoric acid, provided with a back contact in form of a 150 nm gold contact and structured into several cells which were contacted by spring loaded contact pins and then irradiated with simulated sunlight in a measurement device. The efficiency was determined for 0.5×0.5 cm² cells illuminated under Air Mass 1.5 conditions with an intensity of 1000 W/m².

For the above embodiment, the following values have been determined:

| | |
|---|---|
| Efficiency: | 12.1% |
| Fill factor: | 71.1% |
| Short-circuit current density: | 21.6 mA/cm² |
| Open-circuit voltage: | 790 mV |

In a further experimental series, oxygen and nitrogen were supplied from gas bottles. The efficiency was always determined for all experimental series. Not only the composition of the gas mixture was varied but also the total pressure, the substrate temperature and the activation time.

The following preferred parameters were determined to provide the best possible efficiency. The efficiency is largely independent of the HCl partial pressure at an oxygen partial pressure between 5% and approximately 25%. An efficiency of about 11% could then be achieved in all cases at any desired HCl partial pressure up to more than 30%. Here again, however, the efficiency was better at a lower HCl partial pressure of approximately 2% or less. In this manner, at an oxygen partial pressure of 22% (110 mbar at a total pressure of 500 mbar), an efficiency of 12% or more was achieved at extremely low HCl partial pressure values starting at an HCl partial pressure of 2% (10 mbar) and decreasing the HCl partial pressure to extremely low values. In comparative measurements with an oxygen partial pressure of 60% or more, however, such high efficiency results were achieved only with an HCl partial pressure of approximately 0.1% or less under conditions that were otherwise the same. At a higher HCl partial pressure, the efficiency decreased slowly at first with an increase in HCl content, but then dropped more drastically. At an even higher oxygen content, the decline in efficiency with an increase in HCl content was even steeper above an HCl partial pressure of about 0.2% (1 mbar, with the efficiency amounting to approximately 10% in this case) than was the case at an oxygen partial pressure of 60%.

These trends have also been confirmed by measurement series in which the oxygen concentration and HCl concentration were varied over a wide range. These measurement series show a preferred p(HCl)/p(O₂) ratio between 0.001 and 0.1. In absolute terms, better results were achieved at an oxygen partial pressure above approximately 18% or more and an HCl partial pressure of 1% or less.

From the example given above with the composition of the gas mixture resembling that of air, it was found that the efficiency was more than 12% at a substrate temperature of approximately 390° C. up to approximately 420° C. Above a total pressure of approximately 100 mbar, a remarkable increase in efficiency was observed, rapidly reaching saturation with a further increase in total pressure.

We claim:

1. A method of activating CdTe thin-film solar cells in which substrates have been provided with a CdS and a CdTe layer, said method comprising:
exposing the solar cells to a gas mixture containing HCl, oxygen and nitrogen at a total gas pressure below atmospheric pressure, and the HCl partial pressure of the gas mixture is set at levels between 0.002% and 0.2% of the total gas pressure.

2. A method of activating CdTe thin-film solar cells in which substrates have been provided with a CdS and a CdTe layer, said method comprising:
exposing the solar cells to a gas mixture containing HCl oxygen and nitrogen at a total gas pressure below atmospheric pressure, and the oxygen partial pressure of the gas mixture is adjusted to levels between 5% and 25% of the total gas pressure.

3. The method according to claim 1, characterized in that the total gas pressure is set at a level of more than 100 mbar.

4. The method according to claim 1, characterized in that the total gas pressure is set at a level of below 600 mbar.

5. The method according to claim 2, characterized in that the total gas pressure is set at a level of more than 100 mbar.

6. The method according to claim 2, characterized in that the total gas pressure is set at a level of below 600 mbar.

7. The method according to claim 1, characterized in that the substrate temperature is set at a level between 370° C. and 500° C.

8. The method according to claim 7, characterized in that the substrate temperature is set at a level between 390° C. and 420° C.

9. The method according to claim 2, characterized in that the substrate temperature is set at a level between 370° C. and 500° C.

10. The method according to claim 9, characterized in that the substrate temperature is set at a level between 390° C. and 420° C.

11. The method according to claim 1, characterized in that the gas mixture is produced by using air with the addition of HCl gas and establishing a reduced pressure.

12. The method according to claim 2, characterized in that the gas mixture is produced by using air with the addition of HCl gas and establishing a reduced pressure.

13. The method according to claim 1, characterized in that the activation is carried out in 1 to 15 minutes.

14. The method according to claim 2, characterized in that the activation is carried out in 1 to 15 minutes.

15. The method according to claim 1, characterized in that the nitrogen partial pressure is adjusted to a level of more than 20%, and the oxygen partial pressure is adjusted to a level of less than 60%.

16. The method according to claim 2, characterized in that the HCl partial pressure is adjusted to a level between 0.002% and 2%.

17. The method according to claim 1, characterized in that the HCl partial pressure is adjusted to a level between 0.05% and 0.15%

18. The method according to claim 2, characterized in that the HCl partial pressure is adjusted to a level between 0.05% and 0.15%.
